(19) United States
(12) Patent Application Publication
(10) Pub. No.: US 2013/0264487 A1
(43) Pub. Date: Oct. 10, 2013

(54) RADIATION IMAGING APPARATUS, RADIATION IMAGING SYSTEM, AND METHOD FOR CONTROLLING THE RADIATION IMAGING APPARATUS

(71) Applicant: CANON KABUSHIKI KAISHA, Tokyo (JP)

(72) Inventors: Hideyuki Okada, Honjo-shi (JP); Toshio Kameshima, Kumagaya-shi (JP); Tomoyuki Yagi, Honjo-shi (JP); Katsuro Takenaka, Honjo-shi (JP); Sho Sato, Saitama-shi (JP); Atsushi Iwashita, Honjo-shi (JP); Eriko Sugawara, Honjo-shi (JP)

(21) Appl. No.: 13/853,923

(22) Filed: Mar. 29, 2013

(30) Foreign Application Priority Data
Apr. 4, 2012 (JP) 2012-085495

(51) Int. Cl. G01T 1/16

(52) U.S. Cl. CPC G01T 1/16
USPC 250/393; 250/394

(57) ABSTRACT

A radiation imaging apparatus includes plural pixels arranged in a matrix each including a conversion element and a switch element, plural drive wires arranged in a column direction, a drive circuit configured to sequentially supply a conduction voltage to the plural drive wires and supply a non-conduction voltage to the drive wires other than the drive wire supplied with the conduction voltage among the plural drive wires, and a sensing unit configured to sense radiation irradiation to the pixel, in which the sensing unit includes a sensing circuit configured to sense the radiation irradiation to the pixel on the basis of a current flowing through the drive wire supplied with the non-conduction voltage among the plurality of drive wires.

### BACKGROUND OF THE INVENTION

1. Field of the Invention

The present invention relates to a radiation imaging apparatus and system used for medical diagnosis and industrial non-destructive testing, and a method for controlling the radiation imaging apparatus. The invention particularly relates to a radiation imaging apparatus and system that are used to detect the presence of radiation irradiation where a radiation generation apparatus repeats start and stop of radiation irradiation, and a method for controlling the radiation imaging apparatus.

2. Description of the Related Art

A radiation imaging apparatus using a flat panel detector (which will be abbreviated as FPD) synchronizes an imaging operation with radiation irradiation by a radiation generation apparatus. As proposed in International Publication No. WO 2000/065825, the following technique may be used as a technique for this synchronization. In this technique, a bias current flowing through a bias line to a conversion element is monitored to sense the radiation irradiation by the radiation generation apparatus. The bias current is supplied to a switch element while changing a state of the switch element between conductive and non-conductive. An operation of the radiation imaging apparatus is controlled in accordance with a result of the monitoring. However, in the case of using this synchronization technique, as proposed in Japanese Patent Laid-Open No. 2010-268171, a problem may occur. That is, noise is generated at the time of switching between the conductive state and the non-conductive state of the switch element and affects the current flowing through the line that supplies the bias voltage to the conversion element to decrease an accuracy of the monitoring. To reduce the influence of this noise, Japanese Patent Application Laid-Open No. 2010-268171 describes the following suggestions. In the first suggestion, a filter circuit is provided between a current sensing unit and the bias line. In the second suggestion, a sample and hold circuit is formed at a side of an output terminal of the current sensing unit and the sample and hold circuit performs intermittent operation at a time of switching between the conductive state and the non-conductive state of the switch element. In the third suggestion, a noise waveform, which is previously obtained and stored in a storage unit, is subtracted from a current waveform affected by noise component. In the fourth suggestion, two timings are synchronized in order to cancel the noise. The two timings are; a timing of supplying a voltage for a certain row of switch elements for setting the switch elements to the non-conductive state (hereinafter, this voltage is referred to non-conduction voltage); and a timing of supplying another voltage for another row of switch elements for setting the switch elements to the conductive state (hereinafter, this voltage is referred to conduction voltage).

However, to detect the presence of the radiation irradiation more immediately and more accurately, the suggestions of Japanese Patent Application Laid-Open No. 2010-268171 are insufficient. According to the first suggestion, since a band of the filter circuit is limited due to the timing of the switching, a time delay becomes large in the detection operation. According to the second suggestion, when the radiation irradiation starts during a suspension period of the sample and hold circuit, the detection operation is not conducted until a resumption of the operation of the sample and hold circuit. This also causes a problem of time delay. According to the third and fourth suggestions, since variations in resistances and capacitances of wires in a pixel array and variations in characteristics and performances of switch elements cause variations in noise waveforms in a pixel array, and it is difficult to sufficiently reduce the noise influence. This causes a problem of inaccurate detection.

### SUMMARY OF THE INVENTION

According to an aspect of the present invention, a radiation imaging apparatus includes a plurality of pixels each including a conversion element configured to convert radiation into charges and a switch element configured to transfer electric signals based on the charges, a plurality of drive wires each connected to a different switch element, a drive circuit configured to sequentially supply a conduction voltage to the plurality of drive wires to set the switch element to a conductive state and supply a non-conduction voltage to the drive wires other than the drive wires supplied with the conduction voltage among the plurality of drive wires to set the switch element to a non-conductive state, and a sensing unit configured to sense radiation irradiation to the pixel, in which the sensing unit includes a sensing circuit configured to sense the radiation irradiation to the pixel on the basis of a current flowing through the drive wire supplied with the non-conduction voltage among the plurality of drive wires.

According to another aspect of the present invention, there is provided a method for controlling a radiation imaging apparatus that includes a plurality of pixels each including a conversion element configured to convert radiation into charges and a switch element configured to transfer electric signals based on the charges, a plurality of drive wires each connected to a different switch element, and a drive circuit configured to sequentially supply a conduction voltage to the plurality of drive wires to set the switch element to a conductive state and supply a non-conduction voltage to the drive wires other than the drive wires supplied with the conduction voltage among the plurality of drive wires to set the switch element to a non-conductive state. The control method includes sensing of radiation irradiation to the pixel on the basis of a current flowing through the drive wire supplied with the non-conduction voltage among the plurality of drive wires, and controlling of an operation of the drive circuit in accordance with the sensed radiation irradiation.

According to the aspects of the present invention, it is possible to provide the radiation imaging apparatus that may sense the presence of the radiation irradiation more immediately and more accurately than conventional technology.

Further features of the present invention will become apparent from the following description of exemplary embodiments with reference to the attached drawings.

### BRIEF DESCRIPTION OF THE DRAWINGS

FIG. 1A is a schematic diagram of a radiation imaging apparatus and system according to a first exemplary embodiment, and FIG. 1B is a circuit diagram for one pixel of the radiation imaging apparatus, according to the first exemplary embodiment.

FIG. 2A and FIG. 2B are schematic equivalent circuit diagrams of the radiation imaging apparatus according to the first exemplary embodiment.

FIG. 3 is a schematic equivalent circuit diagram of a detection circuit and a sensing circuit according to the first exemplary embodiment.

FIG. 4 is a timing chart for the radiation imaging apparatus according to the first exemplary embodiment.

FIG. 5A and FIG. 5B are schematic equivalent circuit diagrams for one pixel according to another example.

FIG. 6A is a schematic diagram of a radiation imaging apparatus and system according to a second exemplary embodiment, and FIG. 6B is a schematic equivalent circuit diagram of the radiation imaging apparatus according to the second exemplary embodiment.

FIG. 7 is a schematic equivalent circuit diagram of a detection circuit and a sensing circuit according to the second exemplary embodiment.

FIG. 8A is a schematic diagram of a radiation imaging apparatus and system according to a third exemplary embodiment, and FIG. 8B is a schematic equivalent circuit diagram of the radiation imaging apparatus according to the third exemplary embodiment.

FIG. 9A is a schematic equivalent circuit diagram of a detection circuit and a sensing circuit according to the third exemplary embodiment, and FIGS. 9B to 9E are schematic equivalent circuit diagrams for describing an operation of a unit circuit of a driver circuit according to the third exemplary embodiment.

FIG. 10 is a schematic equivalent circuit diagram of a detection circuit and a sensing circuit according to another example.

### DESCRIPTION OF THE EMBODIMENTS

Hereinafter, exemplary embodiments of the present invention will be described with reference to the drawings. Radiation in the present invention includes alpha rays, beta rays, gamma rays, and the like corresponding to beams made of particles (including photons) released from radiation decay as well as beam having comparable energy or above such as X-rays, particle rays, and cosmic rays.

### First Exemplary Embodiment

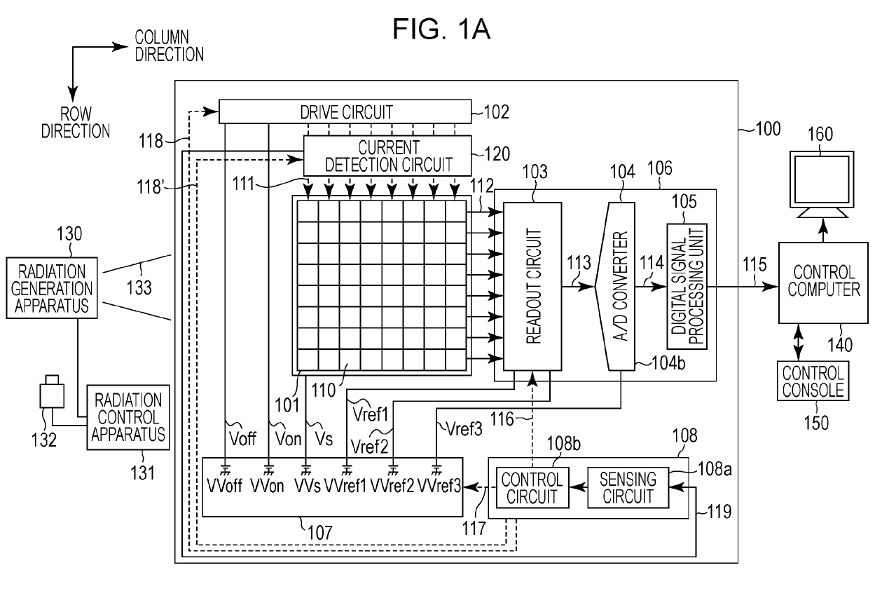

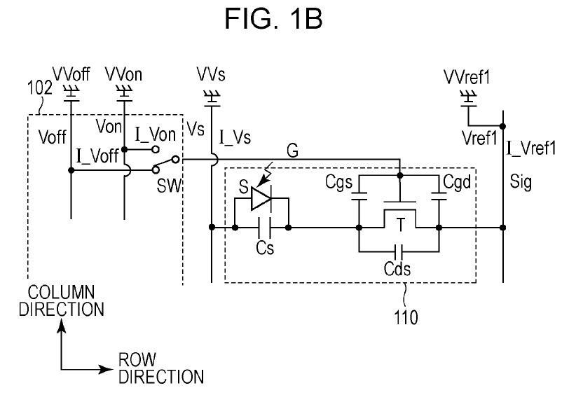

One aspect of the first exemplary embodiment will be described by referring FIG. 1B. FIG. 1B illustrates a schematic equivalent circuit of one pixel in a pixel array provided with plural pixels in a matrix according to the first exemplary embodiment. The pixel array herein refers to an area including an area where plural pixels are arranged and an area between the plural pixels on a substrate where the plural pixels are arranged in a matrix. One pixel 110 illustrated in FIG. 1B includes a conversion element S provided with a semiconductor layer between two electrodes configured to convert radiation into charges and a switch element T configured to transfer electric signals in accordance with the charges. An indirect-type conversion element provided with a photoelectric conversion element and a wavelength conversion body configured to convert radiation into light in a spectrum band that may be sensed by the photoelectric conversion element or a direct-type conversion element configured to directly convert radiation into charges is preferably used for the conversion element S. According to the present embodiment, a PIN-type photo diode that is arranged on an insulating substrate such as a glass substrate and contains amorphous silicon as a main material is used for a photo diode as one type of the photoelectric conversion element. The conversion element S herein has a capacitance, and the capacitance of the conversion element S is denoted by Cs. A transistor including a control terminal and two main terminals is preferably used for the switch element T, and according to the present embodiment, a thin film transistor (TFT) is used. One electrode (first electrode) of the conversion element S is electrically connected to one of the two main terminals of the switch element T, and the other electrode (second electrode) is electrically connected to a bias power supply VVs for supplying a bias voltage via a bias line Vs. A control terminal of the switch element T configured to transfer electric signals in accordance with a potential at the first electrode of the conversion element S is connected to a drive wire G, and drive signals including a conduction voltage for setting the switch element T to a conductive state and a non-conduction voltage for setting the switch element T as a non-conductive state are supplied from a drive circuit 102 via the drive wire G. According to the present embodiment, one main terminal of the switch element T is connected to the first electrode of the conversion element S, and the other main terminal is connected to a signal wire Sig. While the control terminal is supplied with the conduction voltage to set the switch element T to the conductive state, the switch element T transfers the electric signals in accordance with the voltage potential at the first electrode which varies in accordance with the charges generated in the conversion element S to the signal wire Sig. The switch element T has capacitance between the control terminal and the one main terminal, and the capacitance is denoted as Cgd. The switch element T has a capacitance between the control terminal and the other main terminal, and the capacitance is denoted as Cgs. The switch element T also has a capacitance between the two terminals, and the capacitance is denoted as Cds. The signal wire Sig is connected to a reference power supply VVref1 via a reference voltage wire Vref1 for supplying a reference voltage to a readout circuit 103 which will be described below. The drive wire G is selectively connected, through a switch SW provided on the drive circuit 102, to a conduction power supply VVon via a conduction voltage wire Von for supplying the conduction voltage and a non-conduction power supply VVoff via a non-conduction voltage wire Voff for supplying the non-conduction voltage. The pixel array includes the plural pixels 110 arranged in the matrix and the plural drive wires G respectively connected to the mutually different switch elements T. The drive circuit 102 sequentially supplies the conduction voltage to the plural drive wires G and supplies the non-conduction voltage to the drive wires G except for the drive wire G that is supplied with the conduction voltage among the plural drive wires G.

A current that flows when the conversion element S is irradiated with radiation will be described. A case in which the switch element T is in the non-conductive state and the conversion element S is irradiated with radiation will be described. Currents flow through the respective wires in accordance with the generate electron-hole pair, the capacitance Cs of the conversion element S, and the respective capacitances (Cgs, Cgd, and Cds) of the switch element T. The potential at the first electrode of the conversion element S decreases in accordance with the generated charges. Thus, a non-conduction power supply current I_Voff flows as a drive wire current I_Vg from the non-conduction power supply VVoff towards the pixel 110 through the drive wire G in accordance with a decreased amount of the potential at the first electrode and a capacitance ratio or the conversion element S to the drive wire G. A case in which the switch element T is set to the conductive state and the conversion element S is irradiated with radiation will be described. A bias line current I_Vs flows from the pixel 110 towards the bias power supply VVs through the bias line Vs in accordance with the generated hole. A signal wire current I_Vref1 corresponding to a value obtained by dividing the bias line current I_Vs by a product of the capacitance Cs of the conversion element S and an on resistance value Ron of the switch element T flows from the reference power supply VVref1 towards the pixel 110 through the signal wire Sig. A potential difference corresponding to a product of a signal wire current I_Vref1 and the on resistance Ron of the switch element T is generated between a potential Vref1 at the signal wire Sig and a potential at the first electrode of the conversion element S at this time. To cancel the potential difference, a conduction power supply current I_Von flows as the drive wire current I_Vg from the conduction power supply VVon towards the pixel 110 through the drive wire G. It is noted that the on resistance Ron of the switch element T is sufficiently low, an off resistance Roff of the switch element T is sufficiently high, and the capacitance Cds is sufficiently low. For that reason, the drive wire current I_Vg at a time when the switch element T is in the conductive state has an extremely lower value than the drive wire current I_Vg at a time when the switch element T is in the non-conductive state.

A current that flows when the conductive state and the non-conductive state of the switch element T are switched will be described. A current that flows when the non-conductive state of the switch element T is switched to the conductive state will be described first. The conduction power supply current I_Von flows from the conduction power supply VVon towards the pixel 110 as the drive wire current I_Vg through the drive wire G to compensate a potential fluctuation amount between the non-conduction voltage and the conduction voltage. A current that flows when the conductive state of the switch element T is switched to the non-conductive state the switch element T will be described next. The non-conduction power supply current I_Voff flows from the pixel 110 towards the non-conduction power supply VVoff as the drive wire current I_Vg to cancel the potential fluctuation amount between the conduction voltage and the non-conduction voltage.

Thus, the inventors of the present application finds out as a result of earnest examinations that in a case where the conversion element S is irradiated with the radiation, the current flowing through the drive wire G when the switch element T is in the non-conductive state is substantially larger than the current flowing through the drive wire G when the switch element T is in the conductive state. It is also found out that when the conductive state and the non-conductive state of the switch element T are switched, a large current associated with the potential difference between the conduction voltage and the non-conduction voltage flows through the drive wire G, and this current causes the decrease in the sensing accuracy as the noise.

In view of the above, according to the exemplary embodiment of the present invention, a current flowing through the drive wire G supplied with the non-conduction voltage by the drive circuit 102 is detected among the plural drive wires G arranged on a pixel array 101. The drive wire G supplied with the non-conduction voltage herein corresponds to the drive wire G except for the drive wire G where the switching from the non-conduction voltage to the conduction voltage is being carried out in mid-course, the drive wire G supplied with the conduction voltage, and the drive wire G where the switching from the conduction voltage to the non-conduction voltage is being carried out in mid-course among the plural drive wires G. Since the detected current is substantially larger the current flowing through the drive wire G in a case where the switch element T is in the conductive state, the sensing accuracy may be improved as compared with the sensing based on the current flowing through the drive wire G in a case where the switch element T is in the conductive state. Since the current flowing through the drive wire G supplied with the non-conduction voltage is detected, the current corresponding to a noise component which flows when the conductive state of the switch element T is switched to the non-conductive state is suppressed from being mixed into the detected current is suppressed. The drive circuit 102 sequentially supplies the conduction voltage to the plural drive wires G, and the non-conduction voltage is supplied to the drive wire G except for the drive wire G supplied with the conduction voltage among the plural drive wires G. For that reason, the plural drive wire G supplied with the non-conduction voltage regularly exists among the plural drive wires G. The presence of the radiation irradiation to the pixel such as the start or end of the radiation irradiation is sensed on the basis of the detected current. For that reason, the presence of the radiation irradiation may be sensed without interruption, and it is possible to secure the sensing instantaneousness. The decrease in the sensing accuracy caused by the noise component is thus suppressed, and the presence of the radiation irradiation such as the start or end of the radiation irradiation may be sensed with a still higher instantaneousness and also at a high accuracy.

A radiation imaging system and a radiation imaging according to the exemplary embodiment of the present invention will be described next by using FIG. 1A. A radiation imaging apparatus 100 includes the pixel array 101 where the plural pixels 110 are arranged in the pixel, the drive circuit 102 configured to drive the pixel array 101, and a signal processing unit 106 including the readout circuit 103 configured to read out the image signals based on the electric signals from the driven pixel array 101. The signal processing unit 106 includes the readout circuit 103, an A/D converter 104, and a digital signal processing unit 105. According to the present embodiment, to simplify the description, the pixel array 101 includes the pixels 110 arranged in eight rows and eight columns. The pixel array 101 is driven in accordance with a drive signal 111 from the drive circuit 102, and electric signals 112 are output in parallel from the pixel array 101. The electric signals 112 output from the pixel array 101 are read out by the readout circuit 103. An electric signal 113 from the readout circuit 103 is converted from an analog signal to a digital signal 114 by the A/D converter 104. The digital signal from the A/D converter 104 is subjected to simple digital signal processing such as digital multiplex processing or offset correction by the digital signal processing unit 105, and digital image signals are output. The radiation imaging apparatus 100 includes a power supply unit 107 and a control unit 108 configured to supply control signals to the respective components to control operations. The power supply unit 107 includes a first reference power supply VVref1 configured to provide the reference voltage to the readout circuit 103 via the reference voltage wire Vref1 and a second reference power supply VVref2 configured to provide the reference voltage via a reference voltage wire Vref2. The power supply unit 107 includes a third reference power supply VVref3 configured to supply the reference voltage to the A/D converter 104 via a reference voltage wire Vref3. The power supply unit 107 also includes the conduction power supply VVon for supplying the conduction voltage to the drive circuit 102 via the conduction voltage wire Von and the non-conduction power supply VVoff for supplying the non-conduction voltage via the non-conduction voltage wire Voff. The power supply unit 107 further includes the bias power supply VVs for supplying the bias voltage. The control unit 108 controls the drive circuit 102, the readout circuit 103, and the power supply unit 107. The radiation imaging apparatus 100 is provided with a current detection circuit 120 configured to detect a current flowing through the drive wire G. The control unit 108 includes a sensing circuit 108a configured to sense the start of radiation irradiation to the pixel array 101 on the basis of the current detected by the current detection circuit 120 and a control circuit 108b configured to control the drive circuit 102 on the basis of the sensing result of the sensing circuit 108a. A sensing unit according to the embodiment of the present invention includes the current detection circuit 120 and the control circuit 108b and senses at least the start of the start of radiation irradiation to the pixel array 101. The sensing unit will be described in detail below.

A radiation control apparatus 131 performs a control on an operation for a radiation generation apparatus 130 to emit radiation 133 in response to a control signal from an exposure button 132. A control console 150 inputs information on a subject and an imaging condition to a control computer 140 to be transmitted to the control computer 140. A display apparatus 163 displays image data subjected to image processing by the control computer 140 that has received the image data from the radiation imaging apparatus 100.

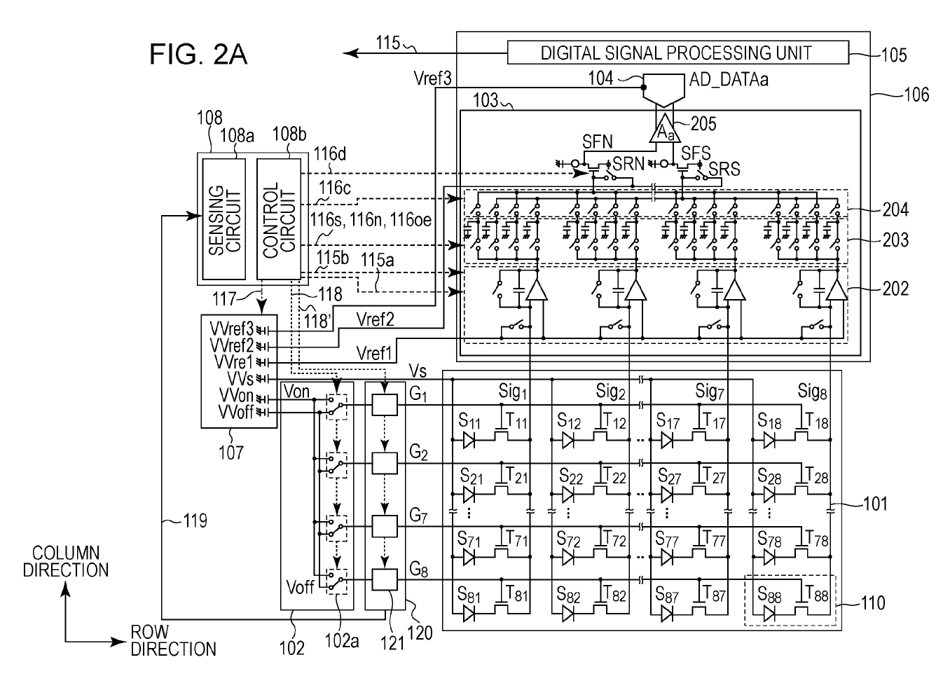

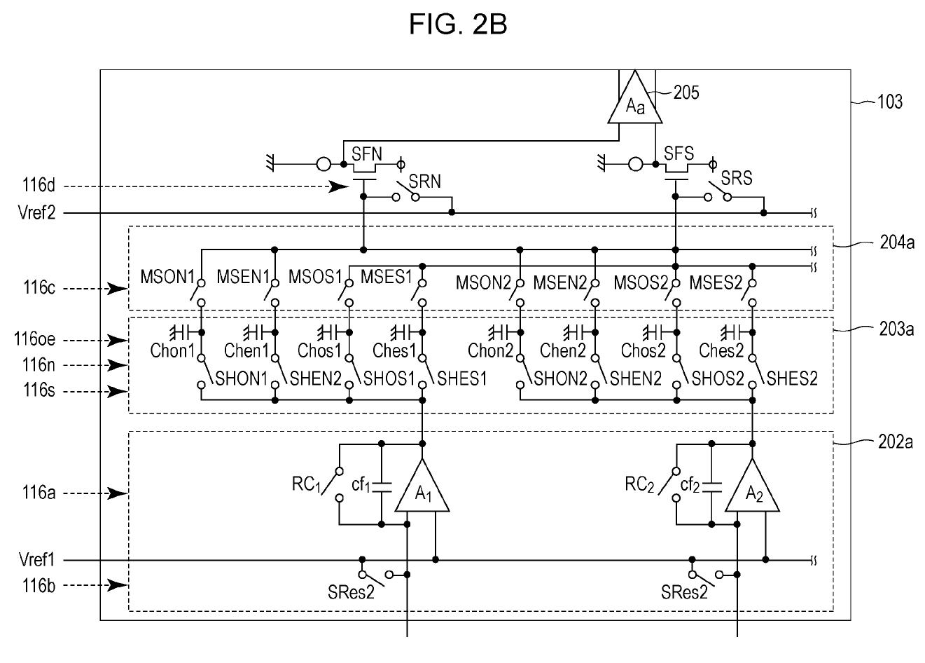

A radiation imaging apparatus according to the present embodiment will be described next by using FIG. 2A and FIG. 2B. FIG. 2A is a schematic equivalent circuit diagram of the radiation imaging apparatus according to the present embodiment, and FIG. 2B is a schematic equivalent circuit diagram of the readout circuit 103. Configurations that are same as the configurations described by using FIG. 1A and FIG. 1B are assigned by the same reference signs, and a detailed description thereof will be omitted.

With regard to switch elements of plural pixels in a row direction such as, for example, T₁₁ to T₁₈, the control terminals of those switch elements are commonly electrically connected to a drive wire G₁ on a first row and receive drive signals from the drive circuit 102 via the drive wire G₁ in units of row. With regard to switch elements of plural pixels in a column direction such as, for example, T₁₁ to T₈₁, the other main terminal of those switch elements are electrically connected to a signal wire Sig₁ on a first column and transfer electric signals in accordance with charges of the conversion element S to the readout circuit 103 via the signal wire Sig₁ while in the conductive state. Plural signal wires Sig₁ to Sig₈ arranged in the column direction transmit electric signals output from the plural pixels in the pixel array 101 to the readout circuit 103 in parallel.

The drive circuit 102 includes plural unit circuits 102a. The plural unit circuits 102a are provided while corresponding to the drive wires G on a one-to-one basis and supply the conduction voltage or the non-conduction voltage to each of the drive wires G. The unit circuit 102a includes the switch SW that selects the connection between the drive wire G and the conduction power supply VVon and the connection between the drive wire G and the non-conduction power supply VVoff.

The readout circuit 103 includes an amplification circuit unit 202 configured to amplify the electric signals output in parallel from the pixel array 101 and a sample and hold circuit unit 203 that samples and holds the electric signals from the amplification circuit unit 202. The amplification circuit unit 202 includes an amplification circuit while corresponding to each of the signal wires Sig. The amplification circuit includes an operational amplifier A configured to amplify and output the read electric signals, an integral capacitance group Cf, and a reset switch RC configured to reset the integral capacitance. The output electric signals are input to an inverting input terminal of the operational amplifier A, and the amplified electric signals are output from an output terminal. The reference voltage wire Vref1 is connected to a non-inverting input terminal of the operational amplifier A. The amplification circuit unit 202 is provided with a signal wire reset switch SRes configured to connect the reference voltage wire Vref1 to the signal wire Sig until the start of the radiation irradiation is sensed. Since consumed power is increased when the operational amplifier A is operated until the start of the radiation irradiation is sensed, the operation of the operational amplifier A is stopped. The signal wire reset switch SRes connects the reference voltage wire Vref1 with the signal wire Sig to fix a voltage of the signal wire Sig at the reference voltage and detect (monitor) the current flowing through the signal wire Sig. The sample and hold circuit unit 203 includes four lines of a sample and hold circuit composed of a sampling switch SH and a sampling capacitance Ch while corresponding to the respective amplification circuits. This is because correlated double sampling (CDS) processing for suppressing offset generated in the amplification circuit is conducted while corresponding to the electric signals for two rows. The readout circuit 103 includes a multiplexer 204 configured to sequentially output the electric signals read out in parallel from the sample and hold circuit unit 203 as image signals in the form of serial signals. The readout circuit 103 further includes an output buffer circuit SF configured to perform impedance conversion on the image signals to be output, an input reset switch SR configured to reset the input of the output buffer circuit SF, and a variable amplifier 205. The multiplexer 204 each includes switches MS1 to MS8 and switches MN1 to MN8 while corresponding to the respective signal wires Sig and performs an operation of converting parallel signals into serial signals by sequentially selecting the respective switches. A fully-differential amplifier as a differential amplifier for the CDS processing is used for the variable amplifier 205. The signals converted into the serial signals are input to the A/D converter 104 and converted into digital data by the A/D converter 104, and the digital data is sent to the digital signal processing unit 105.

The current detection circuit 120 includes plural current detection mechanisms 121, and the plural current detection mechanisms 121 are provided on a one-to-one basis with respect to the unit circuit 102a and the drive wire G. The current detection mechanism 121 will be described below in detail.

The control circuit 108b supplies control signals 118 to the respective unit circuits 102a of the drive circuit 102 and supplies control signals 118′ to the respective current detection mechanisms 121 on the basis of the sensing result of the sensing circuit 108a. Thus, the control circuit 108b may only select the unit circuit 102a selected to be connected to the non-conduction power supply VVoff and the current detection mechanism 121 corresponding to the drive wire G supplied with the non-conduction voltage. To elaborate, the current detection circuit 120 according to the present embodiment may detect a drive current on the drive wire G except for the drive wire G where the non-conduction voltage is switched to the conduction voltage to be supplied, and the conduction voltage is switched to the non-conduction voltage. Impedances of the current detection mechanism 121 and the drive wire G are preferably set to be higher than impedances of the non-conduction power supply VVoff, the bias power supply VVs, and the reference power supply VVref. According to this configuration, a large current accompanied by a potential difference between the conduction voltage and the non-conduction voltage flows into the non-conduction power supply VVoff and does not flow into the current detection mechanism 121 corresponding to the drive wire G supplied with the non-conduction voltage. The sensing circuit 108a senses the presence of the radiation irradiation to the pixel array 101 such as the start or end of the radiation irradiation on the basis of the current detected by the selected current detection mechanism 121. The control circuit 108b supplies a control signal 116a to the reset switch RC of the amplification circuit unit 202 and supplies a control signal 116b to the signal wire reset switch SRes. The control circuit 108b also supplies an even-odd selection signal 116oe, a signal sample control signal 116s, and an offset sample control signal 116n to the sample and hold circuit unit 203. The control circuit 108b further supplies a control signal 116c to the multiplexer 204 and supplies a control signal 116d to the input reset switch SR.

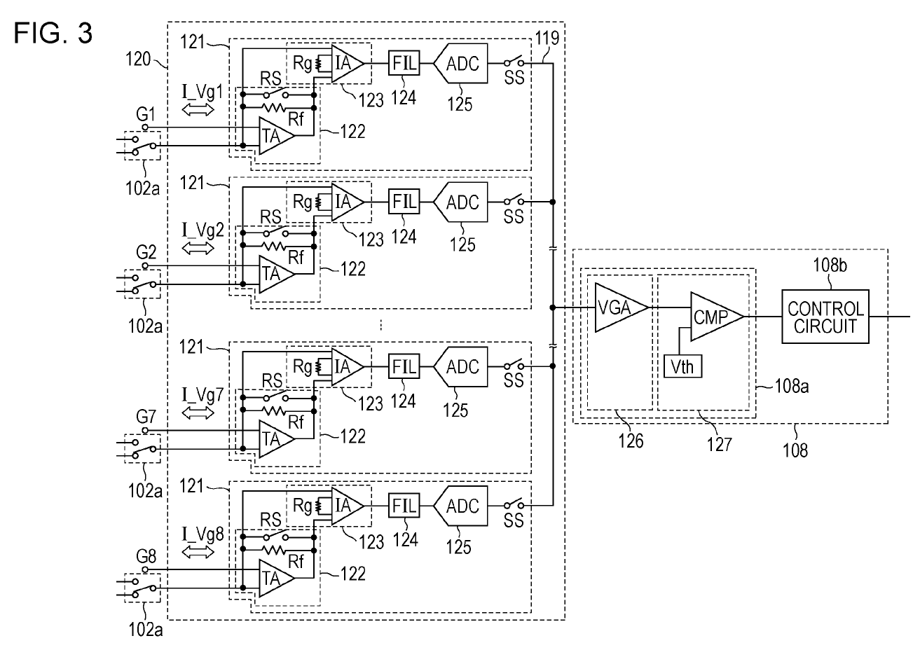

Examples of the current detection circuit 120 and the sensing circuit 108a according to the present embodiment will be described by using FIG. 3. The current detection circuit 120 according to the present embodiment includes the plural current detection mechanisms 121, and the plural current detection mechanisms 121 are provided while corresponding to the unit circuit 102a and the drive wire G on a one-to-one basis. The respective current detection mechanisms 121 include a current voltage conversion circuit 122. According to the present embodiment, the current voltage conversion circuit 122 includes a transimpedance amplifier TA and a feedback resistance Rf. The bias power supply VVs is connected to a non-inverting input terminal of the transimpedance amplifier TA. One of the respective bias lines Vs is connected to an inverting input terminal of the transimpedance amplifier TA. The feedback resistance Rf is connected in parallel with the transimpedance amplifier TA between the output terminal and the non-inverting input terminal. A short-circuit switch RS is connected in parallel with the feedback resistance Rf. The respective current detection mechanisms 121 according to the present embodiment include a voltage amplification circuit 123 configured to amplify an output voltage of the current voltage conversion circuit 122. According to the present embodiment, the voltage amplification circuit 123 includes an instrumentation amplifier IA and a gain setting resistance Rg. The respective current detection mechanisms 121 according to the present embodiment further include a band limitation circuit 124 for noise reduction and an AD converter 125 configured to perform an analog digital conversion and output respective digital current signals. According to this configuration, the current detection mechanism 121 outputs the current signals obtained by converting the current flowing through the drive wire G into the voltage to be amplified and subjected to the band limitation, and detects the current flowing through the drive wire G. The respective current detection mechanisms 121 according to the present embodiment further include a selection switch SS configured to select a signal from the current detection mechanism 121 corresponding to the drive wire G supplied with the non-conduction voltage in accordance with the control signals 118′ from the control circuit 108b. This function of the selection switch SS is equivalent to a function of a selection according to an embodiment of the present invention. With this configuration, the current detection circuit 120 can detect the current on the drive wire G supplied with the non-conduction voltage except for the drive wire G where the switching from the non-conduction voltage to the conduction voltage is being carried out in mid-course, the drive wire G supplied with the conduction voltage, and the drive wire G where the switching from the conduction voltage to the non-conduction voltage is being carried out in mid-course.

The sensing circuit 108a according to the present embodiment includes a computation circuit 126 configured to compute signals from the current detection circuit 120 and a comparison circuit 127 configured to compare an output (computation result) of the computation circuit 126 with a threshold Vth and output the comparison result. The computation circuit 126 illustrated in FIG. 3 includes a variable amplifier VGA configured to amplify the respective bias line current signals by a wanted amplification factor (coefficient). Thus, the computation circuit 126 outputs the amplified current signals as the comparison result. The comparison circuit 127 illustrated in FIG. 3 includes a comparator CMP configured to compare the comparison result of the computation circuit 126 with the previously set threshold Vth. According to the present embodiment, a fixed voltage value previously set as the threshold Vth is used. It is noted that plural different thresholds are preferably prepared, and the plural different thresholds preferably correspond to the plural current detection mechanisms 121 on a one-to-one basis. The comparison circuit 127 preferably selects the threshold corresponding to the selected current detection mechanism 121 among the plural thresholds from the aspect of the sensing accuracy. This is because the wanted threshold may be adopted in a case where characteristic variations for each of the plural current detection mechanisms 121, characteristic variations for each of the plural unit circuits, and the like exist. The comparison result corresponding to the sensing result of the sensing circuit 108a is supplied to the control circuit 108b, and the control circuit 108b performs the control on the drive circuit 102 on the basis of the comparison result. The current detection circuit 120 and the sensing circuit 108a using the signals obtained by converting the detected current to the voltage have been described above, but the embodiment of the present invention is not limited to the above. The current detection circuit 120 and the sensing circuit 108a according to the embodiment of the present invention may use the detected current as it is, and any comparison circuit may be used for the comparison circuit 127 so long as the comparison result may be output on the basis of the detected current. To elaborate, it suffices if the detection may be carried out while the current detection circuit 120 outputs the current flowing through the drive wire G in the form of any signal. The mode has been described above in which the current detection circuit 120 selects and outputs one of the current detection mechanisms 121 corresponding to the drive wire G supplied with the non-conduction voltage, but the embodiment of the present invention is not limited to the above. A circuit configured to perform addition averaging processing on the outputs of the plural current detection mechanisms 121 corresponding to the drive wire G supplied with the non-conduction voltage may be provided, for example, and the signals after the addition averaging processing may be output to the computation circuit 126. It is possible to reduce the random noise components included in the detected current through the addition averaging. The circuit may be included in the computation circuit 126.

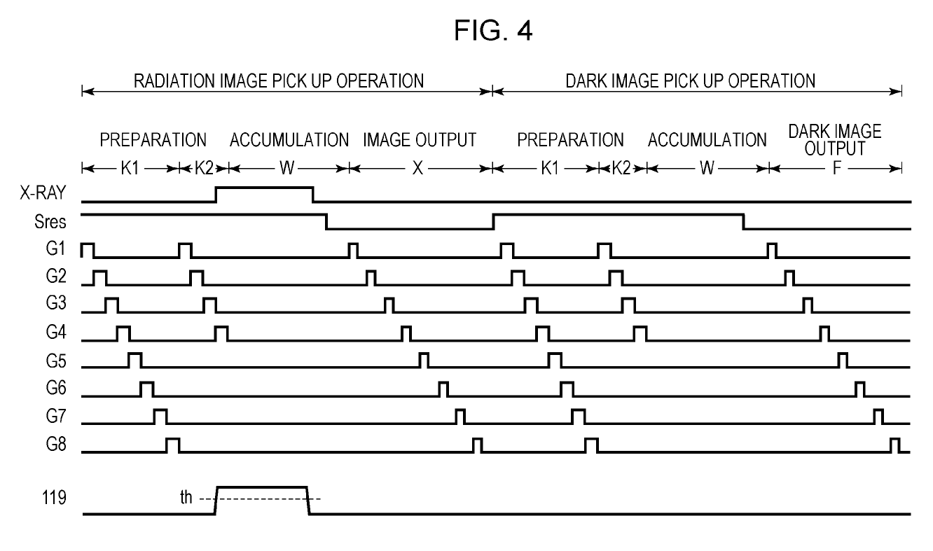

Sensing of the radiation exposure according to the present embodiment and a control based on the sensing will be described by using FIG. 2A, FIG. 3, and FIG. 4. FIG. 4 is a timing chart for the entire radiation imaging apparatus 100.

The control unit 108 supplies control signals 117 to the power supply unit 107 and the current detection circuit 120 in a radiation image pick up operation. Thus, the power supply unit 107 and the current detection circuit 120 supply the bias voltage to the pixel array 101, supply the conduction voltage and the non-conduction voltage to the drive circuit 102, and supply the respective reference voltages to the readout circuit 103. The control unit 108 supplies the control signals 118 to the drive circuit 102, and the drive circuit 102 outputs drive signals so that the conduction voltage is sequentially supplied to the respective drive wires G1 to G8. Thus, an initialization operation K1 where all the switch elements T are sequentially set to the conductive state in units of row, and the initialization operation K1 is carried out plural times until the start of the radiation exposure is sensed. The control unit 108 supplies control signals 116b to the signal wire reset switch SRes of the readout circuit 103 at that time to set the signal wire reset switch Sres to the conductive state. Thus, the first reference power supply VVref1 and the signal wire Sig of the power supply unit 107 are in the conductive state. The current detection circuit 120 detects a first bias line current I_Vs1, a second bias line current I_Vs2, and a third bias line current I_Vs3 during a preparation operation including the initialization operation K1. The current detection circuit 120 outputs current signals 119 from the current detection mechanism 121 corresponding to the drive wire G supplied with the non-conduction voltage to the sensing circuit 108a. The computation circuit 126 amplifies the current signals with respect to the current signals 119. The comparison circuit 127 compares the output of the computation circuit 126 with the threshold Vth and outputs the comparison result to the control circuit 108b. When the output of the computation circuit 126 exceeds the threshold Vth, the current detection circuit 120 and the sensing circuit 108a output the comparison result indicating that the radiation irradiation is started. Thus, the control circuit 108b supplies the control signals 118 to the drive circuit 102 and stops the supply of the conduction voltage to the drive wire G by the drive circuit 102. In FIG. 4, the start of the radiation irradiation is sensed when the conduction voltage is supplied from the drive circuit 102 to the drive wire G4 in an initialization operation K2. The supply of the conduction voltage to the drive wires G5 to G8 is not conducted by the drive circuit 102. All the switch elements T are maintained in the non-conductive state. According to this, the control is conducted in accordance with the start of the radiation irradiation at a time when the operation by the pixel array 101 is sensed so that the initialization operation K2 is ended in the middle of the rows, and the operation by the radiation imaging apparatus 100 is shifted from the preparation operation to an accumulation operation W.

When the end of the radiation irradiation is sensed by the current detection circuit 120 and the sensing circuit 108a, the control circuit 108b supplies the control signals 118 to the drive circuit 102. Thus, the drive circuit 102 outputs the drive signals to sequentially supply the conduction voltages to the respective drive wires G1 to G8, and all the switch elements T are sequentially set to the conductive state in units of row. Thus, the radiation imaging apparatus 100 performs an image output operation X of outputting the electric signals in accordance with the emitted radiation from the pixel array 101 to the readout circuit 103. As described above, the radiation imaging apparatus 100 performs the radiation image pick up operation including the preparation operation, the accumulation operation W, and the image output operation X. An operation period of the initialization operation K1 herein is preferably shorter than an operation period of the image output operation X.

The radiation imaging apparatus 100 performs a dark image pick up operation. Similarly as in the radiation image pick up operation, the dark image pick up operation includes the preparation operation including the initialization operation K1 conducted at least once and the initialization operation K2, the accumulation operation W, and a dark image output operation F. The radiation irradiation is not conducted in the accumulation operation W in the dark image pick up operation herein. The dark image output operation F includes outputting electric signals based on a dark time output derived from a dark current generated in the conversion element S from the pixel array 101 to the readout circuit 103. The operation itself by the radiation imaging apparatus 100 is the same as the image output operation X.

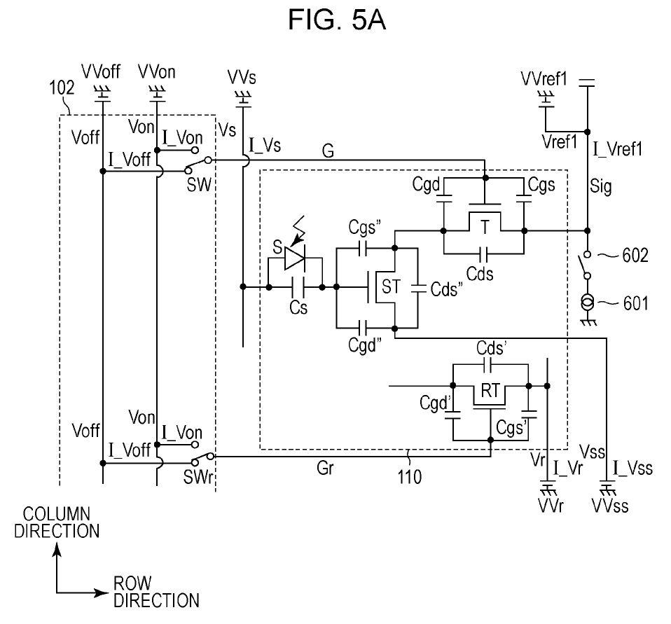

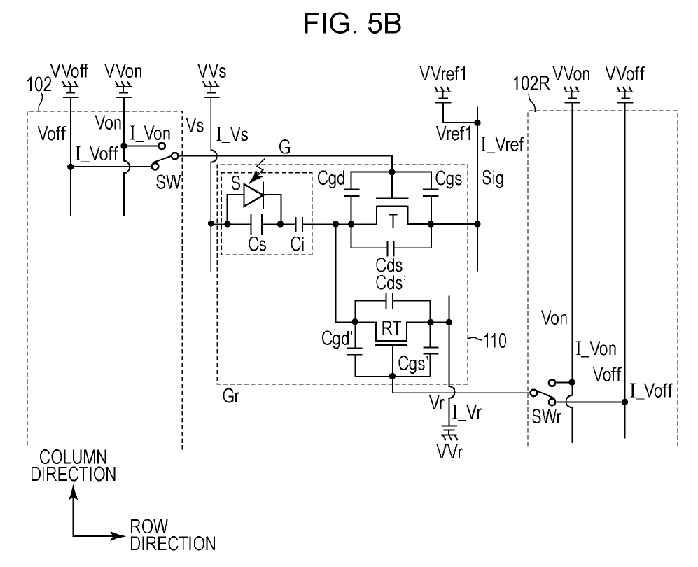

In FIG. 1B and FIG. 2A, the pixel including the conversion element S and the switch element T has been described for the configuration of the single pixel, but the embodiment of the present invention is not limited to the above. As illustrated in FIG. 5A, for example, in addition to the configuration of the single pixel illustrated in FIG. 1B, the pixel 110 may further include an amplification element ST and a reset element RT. In FIG. 5A, a transistor including the control terminal (gate electrode) and the two terminals is used for the amplification element ST. The control terminal of the transistor is connected to one of the electrodes of the conversion element S, the one main terminal is connected to the switch element T, and the other main terminal is connected to an operation power supply VVss that supplies an operation voltage via an operation power supply wire Vss. A constant current source 601 is connected to the signal wire Sig via a switch 602 to constitute a source follower circuit with the amplification element ST. A transistor including the control terminal (gate electrode) and the two terminals is used for the reset element RT. The one main terminal is connected to a reset power supply VVr via a reset wire Vr, and the other main terminal is connected to a control electrode of the amplification element ST. The reset element RT is equivalent to a second switch element according to the embodiment of the present invention, and a voltage of the reset power supply VVr is equivalent to a second voltage according to the embodiment of the present invention. The control electrode of the reset element RT is connected to the drive circuit 102 via a reset drive wire Gr similarly as in the drive wire G. The reset drive wire Gr is selectively connected, via a switch SWr provided in the drive circuit 102, to the conduction power supply VVon via the conduction voltage wire Von or the non-conduction power supply VVoff via the non-conduction voltage wire Voff. A clamp capacitance is provided between the inverting input terminal of the operational amplifier A and the signal wire reset switch SRes. As illustrated in FIG. 5B, for example, in addition to the configuration of the single pixel illustrated in FIG. 1B, the pixel 110 may further include the reset element RT. A transistor including the control terminal (gate electrode) and the two terminals is used for the reset element RT. The one main terminal is connected to the reset power supply VVr via the reset wire Vr, and the other main terminal is connected to the control electrode of the amplification element ST. The reset element RT is equivalent to the second switch element according to the embodiment of the present invention, and a voltage of the reset power supply VVr is equivalent to the second voltage according to the embodiment of the present invention. The control electrode of the reset element RT is connected to a reset drive circuit 102R via the reset drive wire Gr. The reset drive wire Gr is selectively connected, via the switch SWr provided in the reset drive circuit 102R, to the conduction power supply VVon via the conduction voltage wire Von or the non-conduction power supply VVoff via the non-conduction voltage wire Voff. In FIG. 5B, the conversion element S includes an MIS-type photoelectric conversion element. According to the configurations of FIG. 5A and FIG. 5B, the start of the radiation irradiation may also be detected by using the current flowing through the reset drive wire Gr similarly as in the current flowing through the drive wire G.

### Second Exemplary Embodiment

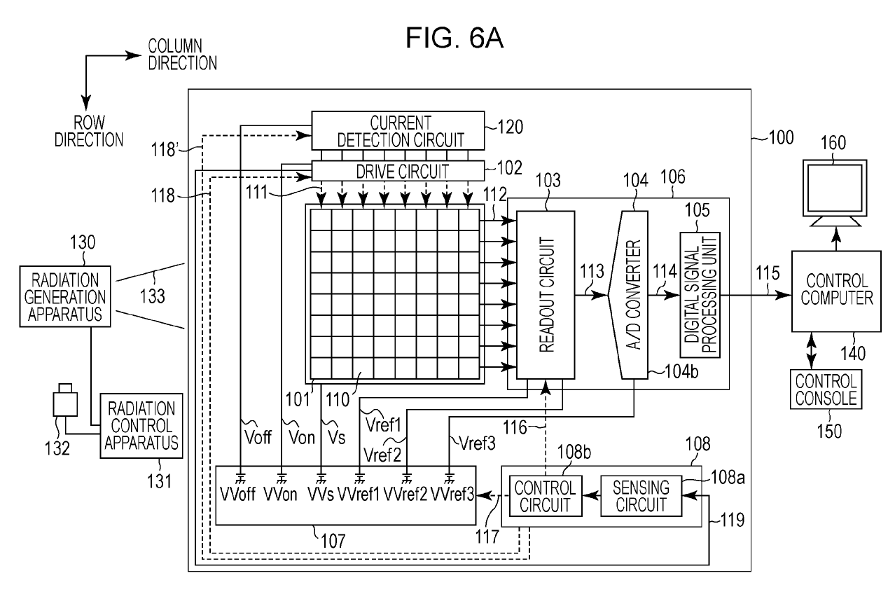

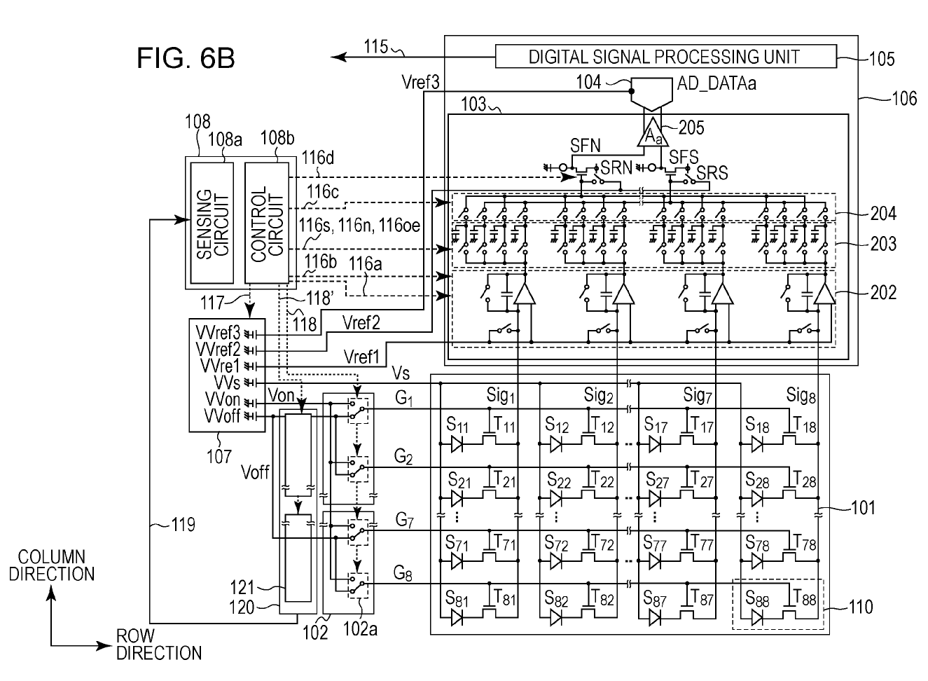

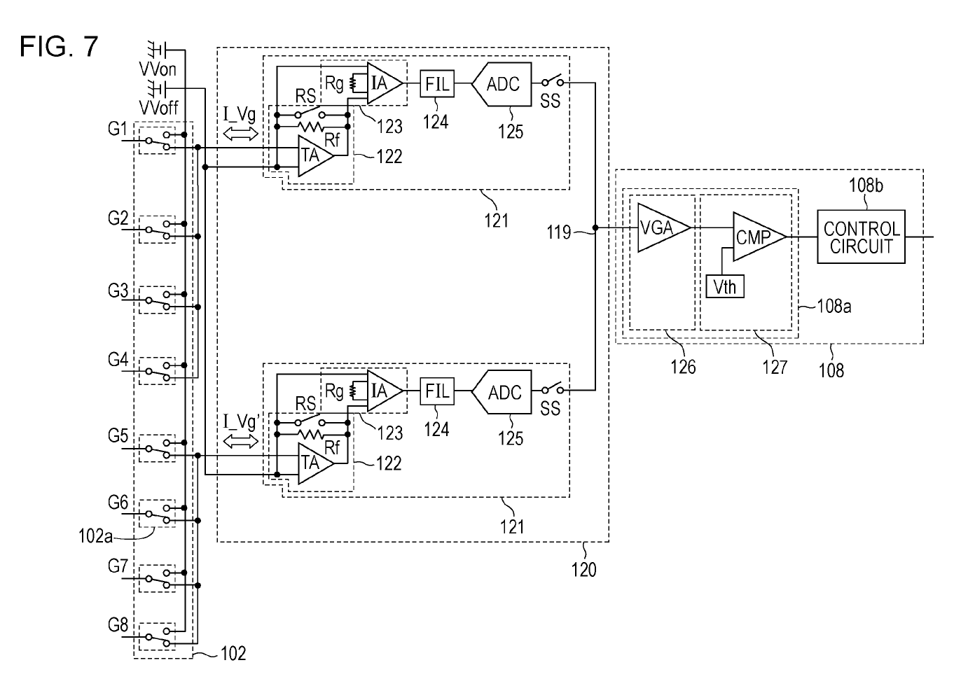

A radiation imaging apparatus according to a second exemplary embodiment of the present invention will be described next by using FIG. 6A, FIG. 6B, and FIG. 7. The same configurations as those described according to the first exemplary embodiment are assigned with the same reference signs, and a detailed description will be omitted. FIG. 6A is a schematic diagram of a radiation imaging apparatus and system according to the present embodiment, and FIG. 6B is a schematic equivalent circuit diagram of the radiation imaging apparatus according to the present embodiment. FIG. 7 is a schematic equivalent circuit diagram of a detection circuit and a sensing circuit according to the present embodiment.

According to the present embodiment, the plural pixels 110 in the pixel array 101 are divided into plural pixel groups, and the plural drive circuits 102 are provided while corresponding to the plural pixel groups. In the example illustrated in FIG. 6B, the plural pixels 110 in the pixel array 101 are divided into two pixel groups. The two drive circuits 102 are provided, and each of the drive circuits 102 corresponds to one pixel group on a one-to-one basis. The current detection circuit 120 includes the two current detection mechanisms 121 provided to the drive circuits 102 on a one-to-one basis. The conduction power supply VVon is commonly directly connected to the respective unit circuits 102a. The non-conduction power supply VVoff is commonly directly connected to the respective unit circuits 102a of the drive circuits 102 via the current detection mechanism 121 for each of the drive circuits 102. With this configuration, the number of the current detection mechanisms 121 can be decreased as compared with the first exemplary embodiment, and the cost reduction accompanied by the reduction in the circuit scale of the radiation imaging apparatus 100.

### Third Exemplary Embodiment

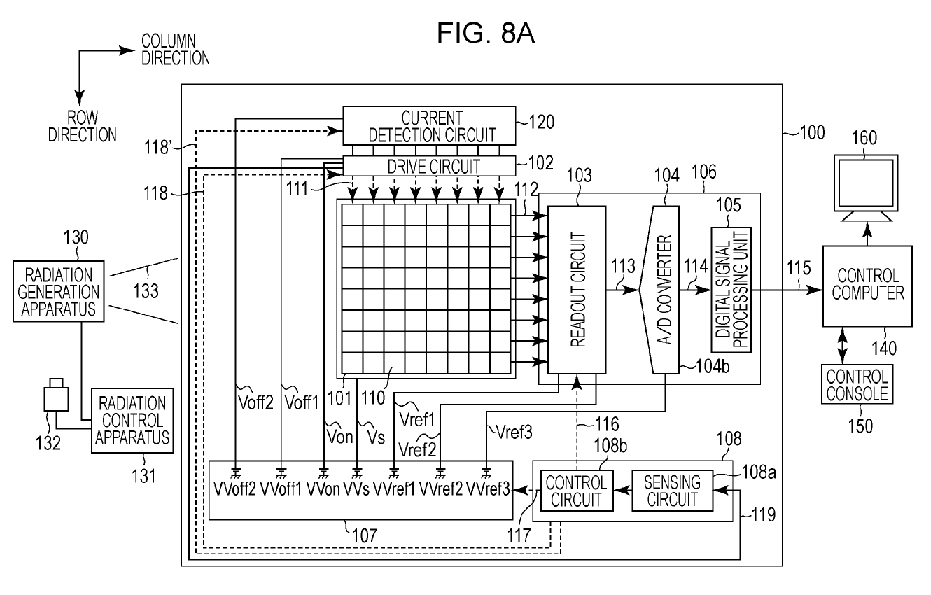

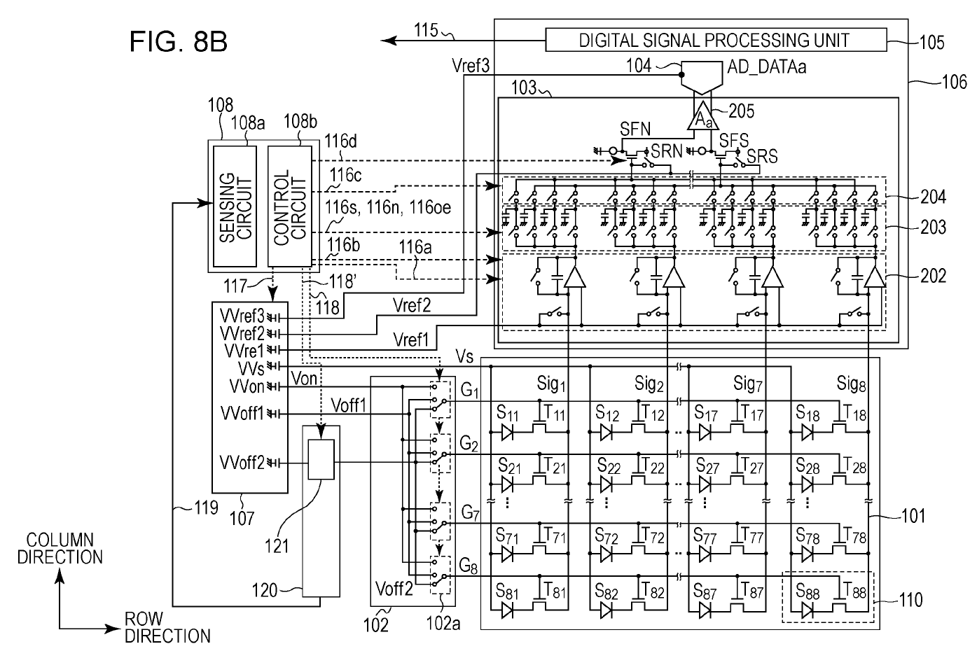

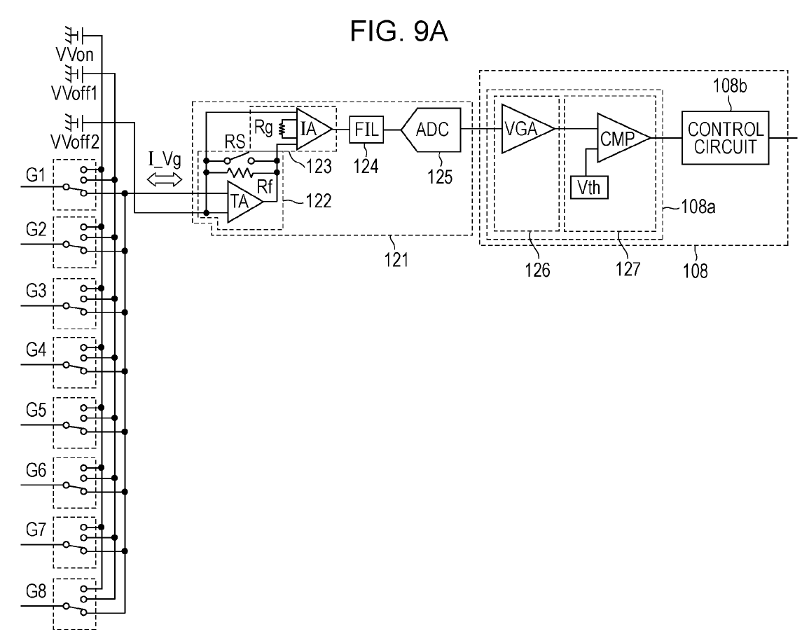

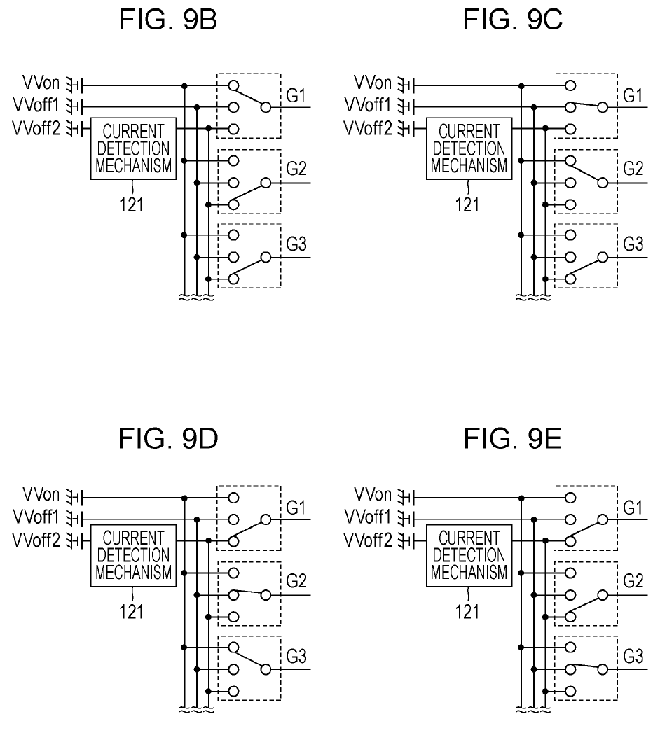

A radiation imaging apparatus according to a third exemplary embodiment of the present invention will be described by using FIG. 8A, FIG. 8B, and FIGS. 9A to 9E. The same configurations as those described according to the first and second exemplary embodiments are assigned with the same reference signs, and a detailed description will be omitted. FIG. 8A is a schematic diagram of a radiation imaging apparatus and system according to the present embodiment, and FIG. 8B is a schematic equivalent circuit diagram of the radiation imaging apparatus according to the present embodiment. FIG. 9A is a schematic equivalent circuit diagram of a detection circuit and a sensing circuit according to the present embodiment, and FIGS. 9B to 9E are schematic equivalent circuit diagrams for describing an operation by the unit circuit of the drive circuit 102 according to the present embodiment.

The power supply unit 107 includes only one line of the non-conduction power supply VVoff according to the first and second exemplary embodiments, but the embodiment of the present invention is not limited to the above. The power supply unit 107 preferably includes the plural non-conduction power supplies VVoff. According to the present embodiment, the power supply unit 107 includes a first non-conduction power supply VVoff1 that commonly supplies the non-conduction voltage to the respective unit circuits 102a without the intermediation of the current detection circuit 120 and a second non-conduction power supply VVoff2 that supplies the non-conduction voltage to the respective unit circuits 102a via the current detection circuit 120. The first non-conduction power supply VVoff1 and the second non-conduction power supply VVoff2 preferably supply the non-conduction voltage having a same voltage value herein, and the first non-conduction power supply VVoff1 is equivalent to another non-conduction power supply according to the embodiment of the present invention. Since FIG. 9A illustrates the mode including only one current detection mechanism 121, as compared with the current detection mechanism 121 according to the first and second exemplary embodiments, the selection switch SS is excluded. It is noted that the configuration is not limited to the above according to the present embodiment. As in the first exemplary embodiment, the plural current detection mechanisms 121 may be provided so as to correspond to the respective unit circuits 102a on a one-to-one basis. As in the second exemplary embodiment, in the mode including the plural drive circuits 102, the plural current detection mechanisms 121 are preferably provided to each of the drive circuits 102 on a one-to-one basis. In this mode, the current detection mechanism 121 preferably includes the selection switch SS similarly as in the first and second exemplary embodiments.

The unit circuit 102a according to the present embodiment may select the connection between the conduction power supply VVon and the drive wire G, the connection between the first non-conduction power supply VVoff1 and the drive wire G, and the connection between the second non-conduction power supply VVoff2 and the drive wire G via the current detection mechanism 121. An example of the operation by the respective unit circuits 102a in which the scanning is sequentially conducted from the drive wire G1 on the first row will be described by using FIGS. 9B to 9E. The unit circuit 102a corresponding to the drive wire G1 on the first row selects the connection with the conduction power supply VVon, and the remaining unit circuits 102a selects the connection with the second non-conduction power supply VVoff2. Thus, the drive wire G1 on the first row is supplied with the conduction voltage, the remaining drive wires G are supplied with the non-conduction voltage. The unit circuit 102a corresponding to the drive wire G2 on the second row selects the connection with the conduction power supply VVon. The unit circuit 102a corresponding to the drive wire G1 on the first row selects the connection with the first non-conduction power supply VVoff1 at that time, and the remaining unit circuits 102a select the connection with the second non-conduction power supply VVoff2. Thus, the current that flows when the voltage supplied to the drive wire G1 on the first row is switched from the conduction voltage to the non-conduction voltage flows towards the first non-conduction power supply VVoff1. Since no path where the current flows towards the second non-conduction power supply VVoff2 exists, the current does not flow into the current detection mechanism 121. The unit circuit 102a corresponding to the drive wire G3 on the third row selects the connection with the conduction power supply VVon. The unit circuit 102a corresponding to the drive wire G2 on the second row selects the connection with the first non-conduction power supply VVoff1 at that time, and the remaining unit circuits 102a including the first row select the connection with the second non-conduction power supply VVoff2. To elaborate, while attention is paid onto the single unit circuit 102a, after the connection with the conduction power supply VVon is selected, the connection with the first non-conduction power supply VVoff1 is selected, and thereafter, the connection with the second non-conduction power supply VVoff2 is selected. With this operation, no path exists where the current that flows when the voltage is switched from the conduction voltage to the non-conduction voltage flows into the current detection mechanism 121, and the mixing of the current corresponding to the noise component into the current detection mechanism 121 is suppressed.

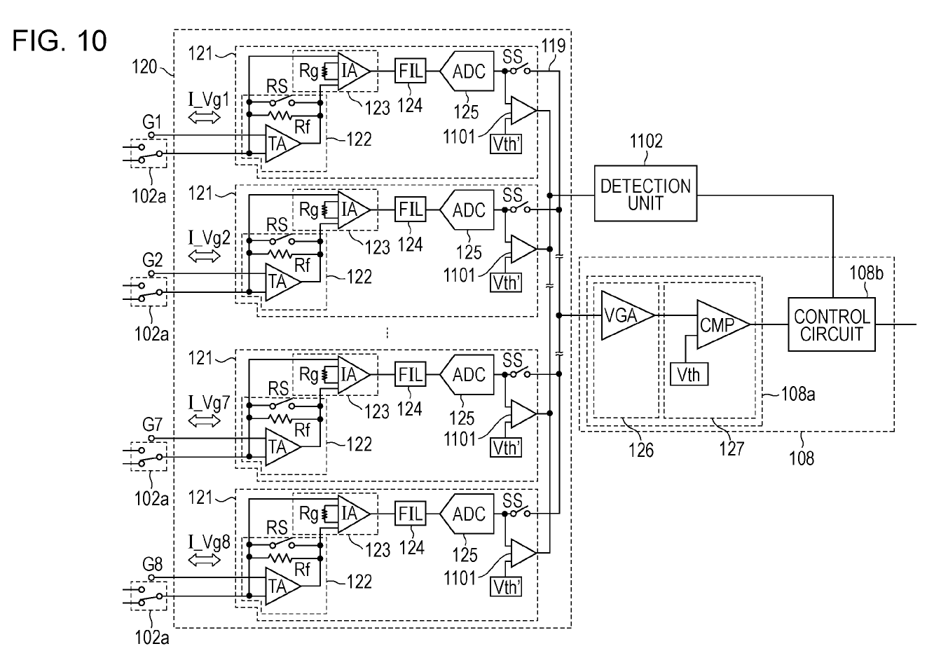

According to the present embodiments of the present invention, in the mode using the plural current detection mechanisms 121, it is possible to detect an area irradiated with the radiation in the pixel array 101 on the basis of the signals output from the plural current detection mechanisms 121. This is because a difference exists between the current flowing through the drive wire G in the area irradiated with the radiation and the current flowing through the drive wire G in the area that is not irradiated with the radiation. For that reason, the output of each of the plural current detection mechanisms 121 is compared with the previously set threshold, and the area irradiated with the radiation in the pixel array 101 can be detected on the basis of the comparison result. As illustrated in FIG. 10, for example, comparators 1101 for the comparison with the threshold are provided to correspond to the respective current detection mechanisms 121 on a one-to-one basis. A detection unit 1102 configured to detect the area irradiated with the radiation in the pixel array 101 on the basis of the outputs of the plural comparators 1101 is provided. With this configuration, it is possible to detect the area irradiated with the radiation in the pixel array 101. The operation of the drive circuit 102 can be controlled so that the control circuit 108b selectively outputs the electric signals from the pixels in the area irradiated with the radiation in the pixel array 101 on the basis of the output of the detection unit 1102.

The respective exemplary embodiments of the present invention can also be realized, for example, while a computer included in the control unit 108 or the control computer 140 executes a program. A unit configured to supply the program to a computer such as, for example, a computer-readable recording medium including a CD-ROM on which the program is recorded or the like or a transmission medium such as the internet through which the program is transmitted can also be adopted as the exemplary embodiments of the present invention. The program can also be adopted as the exemplary embodiments of the present invention. The program, recording medium, transmission medium, and program product are within the scope of the present invention. Technologies based on readily conceivable combinations from the first to third exemplary embodiments are also within the scope of the present invention.

While the present invention has been described with reference to exemplary embodiments, it is to be understood that the invention is not limited to the disclosed exemplary embodiments. The scope of the following claims is to be accorded the broadest interpretation so as to encompass all such modifications and equivalent structures and functions.

This application claims the benefit of Japanese Patent Application No. 2012-085495 filed Apr. 4, 2012, which is hereby incorporated by reference herein in its entirety.

What is claimed is:

1. A radiation imaging apparatus comprising:
a plurality of pixels each including a conversion element configured to convert radiation into charges and a switch element configured to transfer electric signals based on the charges;
a plurality of drive wires each connected to a different switch element;
a drive circuit configured to sequentially supply a conduction voltage to the plurality of drive wires to set the switch element to a conductive state and supply a non-conduction voltage to the drive wires other than the drive wires supplied with the conduction voltage among the plurality of drive wires to set the switch element to a non-conductive state; and
a sensing unit configured to sense radiation irradiation to the pixel,
wherein the sensing unit includes a sensing circuit configured to sense the radiation irradiation to the pixel on the basis of a current flowing through the drive wire supplied with the non-conduction voltage among the plurality of drive wires.

2. The radiation imaging apparatus according to claim 1, further comprising:
a control unit configured to control the drive circuit,
wherein the sensing unit further includes a current detection circuit configured to detect the current flowing through the drive wire supplied with the non-conduction voltage among the plurality of drive wires,
wherein the sensing circuit includes a comparison circuit configured to output a comparison result on the basis of the current flowing through the drive wire, and
wherein the control unit controls the drive circuit on the basis of the comparison result.

3. The radiation imaging apparatus according to claim 2, further comprising:
a power supply unit including a conduction power supply configured to supply the conduction voltage to the drive circuit and a non-conduction power supply configured to supply the non-conduction voltage to the drive circuit,
wherein the non-conduction power supply supplies the non-conduction voltage to the drive wire via the current detection circuit.

4. The radiation imaging apparatus according to claim 3,
wherein the drive circuit includes a plurality of unit circuits,
wherein the plurality of unit circuits are provided to correspond to the plurality of drive wires on a one-to-one basis, and
wherein the non-conduction power supply supplies the non-conduction voltage to the unit circuit via the current detection circuit.

5. The radiation imaging apparatus according to claim 4,
wherein the power supply unit further includes another non-conduction power supply configured to supply the non-conduction voltage to the unit circuit without intermediation of the current detection circuit.

6. The radiation imaging apparatus according to claim 3,
wherein the plurality of pixels are divided into a plurality of pixel groups,
wherein a plurality of the drive circuits are provided to correspond to the plurality of pixel groups on a one-to-one basis, and
wherein the current detection circuit includes a plurality of current detection mechanisms, and
wherein the plurality of current detection mechanisms are provided to correspond to the plurality of drive circuits on a one-to-one basis.

7. The radiation imaging apparatus according to claim 3,
wherein the current detection circuit includes a plurality of current detection mechanisms, and
wherein the plurality of current detection mechanisms are provided to correspond to the plurality of drive wires on a one-to-one basis.

8. The radiation imaging apparatus according to claim 7,
wherein the current detection circuit further includes a selection unit configured to select signals from the plurality of current detection mechanisms, and
the control unit controls the selection unit.

9. The radiation imaging apparatus according to claim 8,
wherein the comparison circuit has a plurality of thresholds,
wherein the plurality of thresholds correspond to the plurality of current detection mechanisms on a one-to-one basis, and
wherein the comparison circuit selects, from among the plurality of thresholds, a threshold corresponding to a current detection mechanism selected from the plurality of current detection mechanisms.

10. The radiation imaging apparatus according to claim 9, further comprising:
a detection unit configured to detect an area including the plurality of pixels which is irradiated with the radiation on the basis of the signals from the plurality of current detection mechanisms,
wherein the control unit controls an operation of the drive circuit on the basis of an output of the detection unit.

11. A radiation imaging system comprising:
the radiation imaging apparatus according to claim 1; and
a radiation generation apparatus configured to emit the radiation.

12. A method for controlling a radiation imaging apparatus that includes a plurality of pixels each including a conversion element configured to convert radiation into charges and a switch element configured to transfer electric signals based on the charges, a plurality of drive wires each connected to a different switch element, and a drive circuit configured to sequentially supply a conduction voltage to the plurality of drive wires to set the switch element to a conductive state and supply a non-conduction voltage to the drive wires other than the drive wires supplied with the conduction voltage among the plurality of drive wires to set the switch element to a non-conductive state, the control method comprising:
sensing radiation irradiation to the pixel on the basis of a current flowing through the drive wire supplied with the non-conduction voltage among the plurality of drive wires; and
controlling an operation of the drive circuit in accordance with the sensed radiation irradiation.

13. The control method for the radiation imaging apparatus according to claim 12,
wherein the sensing of the radiation irradiation to the pixel includes comparing the detected current with a previously set threshold.

14. The control method for the radiation imaging apparatus according to claim 13,
wherein the sensing of the radiation irradiation to the pixel further includes comparing the detected current with a threshold selected from a plurality of previously set thresholds.

15. The control method for the radiation imaging apparatus according to claim 14,
wherein the radiation imaging apparatus further includes a power supply unit including a conduction power supply configured to supply a conduction voltage to the drive circuit and a non-conduction power supply configured to supply the non-conduction voltage to the drive circuit,
wherein the non-conduction power supply supplies the non-conduction voltage to the drive wire via the current detection circuit.

16. The control method for the radiation imaging apparatus according to claim 15,
wherein the drive circuit includes a plurality of unit circuits,
wherein the plurality of unit circuits are provided to correspond to the plurality of drive wires on a one-to-one basis, and
wherein the non-conduction power supply supplies the non-conduction voltage to the unit circuit via the current detection circuit.

17. The control method for the radiation imaging apparatus according to claim 16,
wherein the power supply unit further includes another non-conduction power supply configured to supply the non-conduction voltage to the unit circuit without intermediation of the current detection circuit.
